(19) United States
(12) Patent Application Publication
(10) Pub. No.: US 2018/0122773 A1
(43) Pub. Date: May 3, 2018

(54) SEMICONDUCTOR DEVICE

(71) Applicant: FUJITSU LIMITED, Kawasaki-shi (JP)

(72) Inventor: Toshiaki Nagai, Yokohama (JP)

(73) Assignee: FUJITSU LIMITED, Kawasaki-shi (JP)

(21) Appl. No.: 15/728,605

(22) Filed: Oct. 10, 2017

(30) Foreign Application Priority Data
Nov. 1, 2016 (JP) 2016-214605

(51) Int. Cl. H01L 25/065; H01L 25/18

(52) U.S. Cl. CPC H01L 25/0652; H01L 25/18; H01L 2225/06572; H01L 2225/06541; H01L 2225/06555; H01L 2225/06513

(57) ABSTRACT

A semiconductor device includes: a first chip including one of a logic circuit and a memory circuit and mounted over a substrate with a circuit surface of the first chip facing up; a second chip including the other of the logic circuit and the memory circuit and mounted over the first chip with a circuit surface of the second chip facing down such that the logic circuit and the memory circuit are coupled via a first connection electrode; and a third chip mounted between the substrate and the second chip with a circuit surface of the third chip facing down and includes: an interface circuit that converts between a first signal which is transmitted with the logic circuit or memory circuit and a second signal which is transmitted with an outside; and a first through electrode coupling the logic circuit or memory circuit and the interface circuit.

### CROSS-REFERENCE TO RELATED APPLICATION

This application is based upon and claims the benefit of priority of the prior Japanese Patent Application No. 2016-214605, filed on Nov. 1, 2016, the entire contents of which are incorporated herein by reference.

### FIELD

The embodiment discussed herein is related to a semiconductor device.

### BACKGROUND

Chips are stacked in a semiconductor device.

Related arts are disclosed in Japanese Laid-open Patent Publication Nos. 2012-4432 and 2010-80801.

### SUMMARY

According to an aspect of the embodiments, a semiconductor device includes: a first chip including one of a logic circuit and a memory circuit and mounted over a substrate with a circuit surface of the first chip facing up; a second chip including the other of the logic circuit and the memory circuit and mounted over the first chip with a circuit surface of the second chip facing down such that the logic circuit and the memory circuit are electrically coupled to each other via a first connection electrode; and a third chip mounted between the substrate and the second chip with a circuit surface of the third chip facing down and alongside the first chip, the third chip including: an interface circuit that converts between a first signal which is input to and output from the logic circuit or memory circuit and a second signal which has a signal speed higher than the first signal and is input to and output from an outside; and a first through electrode electrically coupling the logic circuit or memory circuit and the interface circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a semiconductor device;

FIG. 2 illustrates an example of a cross-sectional view of a semiconductor device;

FIG. 3 illustrates an example of a cross-sectional view of a semiconductor device;

FIG. 4 illustrates an example of a cross-sectional view of a semiconductor device;

FIG. 5 illustrates an example of a cross-sectional view of a semiconductor device;

FIG. 6 illustrates an example of a cross-sectional view of a semiconductor device;

FIG. 7 illustrates an example of a cross-sectional view of a semiconductor device;

FIG. 8 illustrates an example of a cross-sectional view of a semiconductor device;

FIG. 9 illustrates an example of a cross-sectional view of a semiconductor device;

FIG. 10 illustrates an example of a semiconductor device;

FIG. 11 illustrates an example of a semiconductor device;

FIG. 12 illustrates an example of a semiconductor device;

FIG. 13 illustrates an example of an enlarged view around an optical circuit;

FIG. 14A illustrates an example of a plan view of a semiconductor device;

FIG. 14B is an example of a cross-sectional view of the semiconductor device taken along line A-A;

FIG. 15 illustrates an example of a plan view of a semiconductor device;

FIG. 16 illustrates an example of a plan view of a semiconductor device;

FIG. 17 illustrates an example of a plan view of a semiconductor device; and

FIG. 18 illustrates an example of a plan view of a semiconductor device.

### DESCRIPTION OF EMBODIMENT

For example, utilizing through-silicon vias (TSVs) formed in a semiconductor chip, multiple chips including a memory chip are stacked on an interface chip. For example, utilizing TSVs, provided is a stack chip in which a memory chip and a processor chip are stacked in this order on an interface chip.

For example, in the stack described above, three or more layers of chips, such as a processor chip, a memory chip, and an interface chip are stacked. For this reason, as the thickness of the stack increases, the stack may tend to deteriorate in heat dissipation characteristics and power supply characteristics. For example, the heat dissipation and the power supply of the stack chip are efficiently performed from the upper surface or the lower surface of the stack chip. However, even if those are performed from both surfaces, the heat dissipation characteristics and the power supply characteristics may tend to deteriorate in middle layers of the stack chip.

For example, when a logic chip including a logic circuit, such as a processor, as a main constituent; a memory chip including a memory circuit as a main constituent; and an interface chip including an interface circuit with the outside as a main constituent are arranged and coupled together, a semiconductor device may be provided which has excellent heat dissipation characteristics and power supply characteristics while reducing the thickness of its stack chip and ensuring large amounts of data communications between the logic chip and the memory chip and between the semiconductor device and the outside thereof.

When semiconductor chips are stacked, the chips are electrically coupled to one another via connection electrodes such as bumps. Electrical connections inside the chip are made, for example, via through electrodes such as TSVs. The formation of through electrodes causes strain in areas in the chip where active elements such as transistors are formed, for example, active areas. To avoid this, active areas are not formed around through electrodes, which may result in a case where the through electrodes are not provided with a high density. In such a case, the in-plane density of the through electrodes is lower than that of connection electrodes. For example, the through electrodes pass through the inside of a semiconductor substrate having electrical conductivity and a high electric permittivity. Although insulation films are provided between the through electrodes and the semiconductor substrate, it is difficult to form thick insulation films. For this reason, the through electrodes have a large capacitive load component and/or complicated impedance frequency characteristics due to parasitic capacitance, depending on the resistivity of the semiconductor substrate, the through electrode shapes and/or the arrangement of the through electrodes.

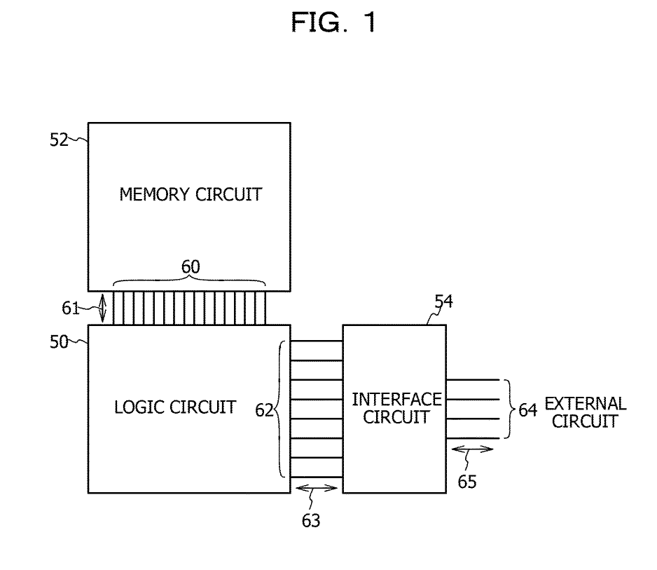

FIG. 1 illustrates an example of a semiconductor device. The semiconductor device mainly includes a logic circuit 50, a memory circuit 52, and an interface circuit 54. The logic circuit 50 is, for example, a chip that mainly performs arithmetic processing, such as a central processing unit (CPU), a graphics processing unit (GPU), and a field-programmable gate array (FPGA). The logic circuit 50 may include other elements, such as a cache memory, as an auxiliary element. The memory circuit 52 is, for example, a cache memory and/or a main memory, and mainly performs storage processing using a storage element. The memory circuit 52 may be, for example, a static random access memory (SRAM), a dynamic random access memory (DRAM), and a magnetoresistive random access memory (MRAM), or the like. The memory circuit 52 may include auxiliary circuits such as a memory interface circuit and a memory controller circuit. The interface circuit 54 may be an interface between the logic circuit 50 and external circuits, may be, for example, a circuit that converts between a parallel signal and a serial signal, and may be, for example, a Serializer/Deserializer (SerDes) circuit.

Signal lines 60 electrically couple the logic circuit 50 to the memory circuit 52. A signal 61 is transmitted through the signal lines 60. The number of the signal lines 60 is, for example, about 8000, and the transmission rate of the signal 61 through a single signal line 60 is, for example, about 2 G bit/s. The data transmission rate between the logic circuit 50 and the memory circuit 52 is, for example, 2 TB (byte)/s. Signal lines 62 are parallel signal lines electrically coupling the logic circuit 50 to the interface circuit 54. A signal 63 is transmitted through the signal lines 62. The number of the signal lines 62 may be, for example, about 1000, and the transmission rate of the signal 63 through a single signal line 62 may be, for example, 2 G bit/s. The data transmission rate between the logic circuit 50 and the interface circuit 54 may be, for example, 250 G bit/s. Signal lines 64 are serial signal lines electrically coupling the interface circuit 54 to an external circuit, and include a single wiring, a differential wiring, or the like. A signal 65 is transmitted through the signal lines 64. The signal lines 64 may be, for example, 40 lanes×2 (transmission and reception). The transmission rate of the signal 65 through a single lane of the signal lines 64 may be, for example, 25 G bit/s. With this, the transmission rate between the interface circuit 54 and the external circuit is, for example, 250 GB (byte)/s.

As described above, to improve the communication band between the logic circuit 50 and the memory circuit 52, the number of the signal lines 60 is larger than that of the signal lines 62 or 64. The transmission rate per lane of the signal lines 64 is much faster than the transmission rate per line of the signal lines 62.

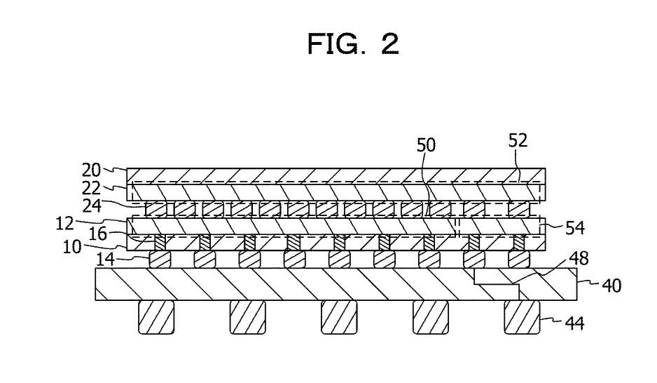

FIG. 2 illustrates an example of a cross-sectional view of a semiconductor device. Chips 10 and 20 are stacked on a substrate 40. The chip 10 is mounted such that a circuit formation layer 12, on which a circuit is formed, faces up, for example, face-up mounting is made. The chip 20 is mounted with a circuit formation layer 22 facing down, for example, face-down mounting. The circuit formation layers 12 and 22 include active elements, such as transistors, formed on semiconductor substrates in the chips 10 and 20, respectively, and multilayer wiring formed on the semiconductor substrate. The circuit formation layer 12 includes a logic circuit 50 and an interface circuit 54. The circuit formation layer 22 includes a memory circuit 52.

Connection electrodes 44 is provided under the substrate 40. The connection electrodes 44 includes terminals for inputting and outputting signals from the semiconductor device to an external circuit, and terminals for supplying a power supply potential and a ground potential from the external circuit to the semiconductor device. Wiring 48 is provided in the substrate 40. The wiring 48 electrically couples the connection electrodes 44 to connection electrodes 14. The connection electrodes 14 are provided under the chip 10. The connection electrodes 14 electrically couple the chip 10 to the substrate 40. Through electrodes 16 which pass through the semiconductor substrate is formed in the chip 10. Through electrodes 16 electrically couple the circuit formation layer 12 to the connection electrodes 14. Connection electrodes 24 are provided under the chip 20. The connection electrodes 24 electrically couple the chip 20 to the chip 10.

In FIG. 2, the chip 10 is face-up mounted, and the chip 20 is face-down mounted. With this face-down mounting, the logic circuit 50 is coupled to the memory circuit 52 via the connection electrodes 24. For this reason, the density of signal lines 60 between the logic circuit 50 and the memory circuit 52 is high. The communication band between the logic circuit 50 and the memory circuit 52 is improved. The connections between the logic circuit 50 and the substrate 40 are mainly power supply lines and ground lines. The capacitive load component of the through electrodes may not adversely affect the power lines and the ground lines. The numbers of the power lines and the ground lines may be smaller than that of the signal lines 60. The logic circuit 50 may be coupled to the substrate 40 via the through electrodes 16, the density of which is low. For example, the interface circuit 54 is coupled to the substrate 40 via the through electrodes 16. Although the number of the signal lines 64 is small, a high speed signal is transmitted through the signal lines 64. For this reason, the high-speed signal transmission may be difficult due to the band limitation of the capacitive load component of the through electrodes 16.

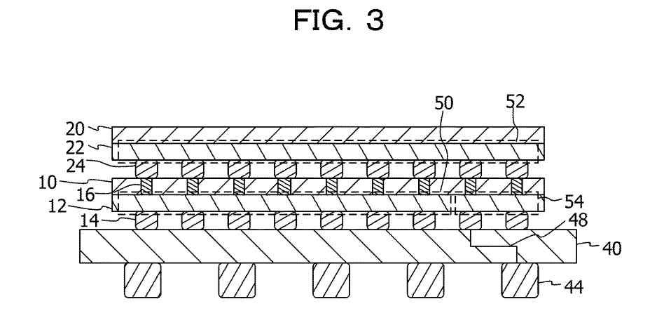

FIG. 3 illustrates an example of a cross-sectional view of a semiconductor device. As illustrated in FIG. 3, chips 10 and 20 are face-down mounted. A circuit formation layer 12 includes a logic circuit 50 and an interface circuit 54, and a circuit formation layer 22 includes a memory circuit 52. In FIG. 3, since other structures are substantially the same as or similar to those illustrated in FIG. 2, descriptions therefor may be omitted.

In FIG. 3, the chip 10 is face-down mounted. For this reason, an interface circuit 54 is coupled to a substrate 40 not via through electrodes 16. As a result, a high-speed signal is transmitted through signal lines 64 because the parasitic capacitance of the through electrodes 16 is not added to the lines and the signal is not subjected to the band limitation. For example, the logic circuit 50 is coupled to the memory circuit 52 via the through electrodes 16. For this reason, the number of signal lines 60 is not increased, and the communication band is narrow. In addition, since the parasitic capacitance of the through electrodes 16 charge and discharge during the communication between the logic circuit 50 and the memory circuit 52, the energy consumption is high.

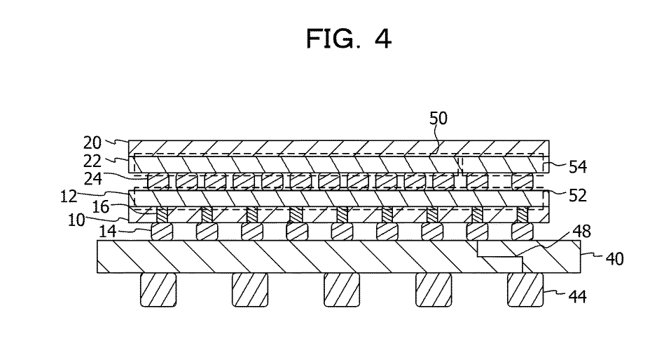

FIG. 4 illustrates an example of a cross-sectional view of a semiconductor device. As illustrated in FIG. 4, a chip 10 is face-up mounted and a chip 20 is face-down mounted. A circuit formation layer 12 includes a memory circuit 52, and a circuit formation layer 22 includes a logic circuit 50 and an interface circuit 54. Since other structures are substantially the same as or similar to those illustrated in FIG. 2, descriptions therefor are omitted.

In FIG. 4, the logic circuit 50 is coupled to the memory circuit 52 via connection electrodes 24. For this reason, signal lines 60 are densely wired as in FIG. 2. For example, the interface circuit 54 is coupled to a substrate 40 via through electrodes 16. For this reason, as in FIG. 2, high-speed signal transmission may be difficult due to the band limitation of the capacitive load component of the through electrodes 16.

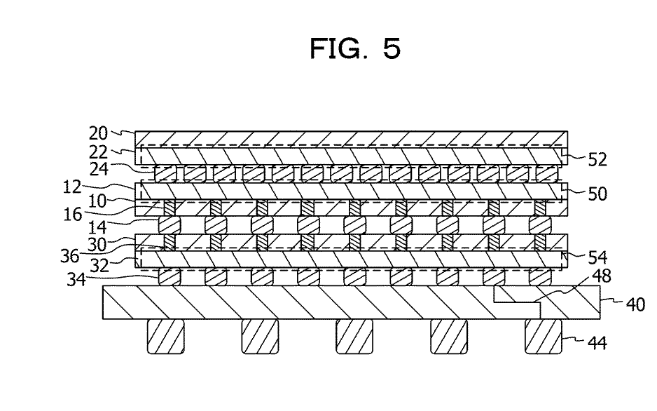

FIG. 5 illustrates an example of a cross-sectional view of a semiconductor. As illustrated in FIG. 5, a chip 10 is face-up mounted and a chip 20 is face-down mounted. A chip 30 is face-down mounted between the chip 10 and a substrate 40. Connection electrodes 34 are provided under the chip 30. The connection electrodes 34 electrically couple a circuit formation layer 32 of the chip 30 to the substrate 40. Through electrodes 36 are provided in the chip 30. The through electrodes 36 electrically couple the circuit formation layer 32 to connection electrodes 14. A circuit formation layer 12 includes a logic circuit 50, a circuit formation layer 22 includes a memory circuit 52, and the circuit formation layer 32 includes an interface circuit 54. Other structures are substantially the same as or similar to those illustrated in FIG. 2, descriptions therefor may be omitted.

In FIG. 5, the logic circuit 50 is coupled to the memory circuit 52 via connection electrodes 24. For this reason, signal lines 60 are densely wired as in FIG. 2. An interface circuit 54 is coupled to the substrate 40 not via through electrodes 16. For this reason, high-speed signal transmission is performed without being affected by the capacitive load component of the through electrodes 16. For example, when the number of stacked chips is large, the semiconductor device may be large. For example, the heat of the stack chip is dissipated efficiently from the upper surface or the lower surface of the stack chip. Power is efficiently supplied to the stack chip from the lower surface of the stack chip. However, with additional wiring for the power supply on the upper surface, the power is also supplied from the upper surface. When heat dissipation or power supply of a stack ship is performed from one surface, heat dissipation characteristics or power supply characteristics may deteriorate in chips away from the surface. For example, when power is supplied from both surfaces, heat dissipation characteristics or power supply characteristics may deteriorate in middle layers of the stack chip.

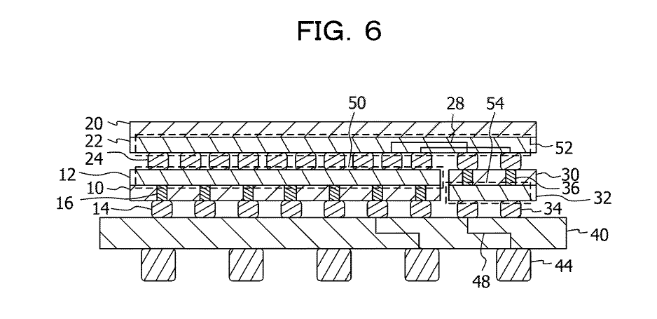

FIG. 6 illustrates an example of a cross-sectional view of a semiconductor device. As illustrated in FIG. 6, a chip 10 is face-up mounted on a substrate 40. A chip 30 is face-down mounted on the substrate 40. A chip 20 is face-down mounted on the chip 10 and chip 30. Connection electrodes 34 are provided under the chip 30. A circuit formation layer 32 is electrically coupled via the connection electrodes 34 and wiring 48 to connection electrodes 44. Through electrodes 36 is provided in the chip 30. The through electrodes 36 electrically couple a circuit formation layer 32 to connection electrodes 24. Wiring 28 in a circuit formation layer 22 couples a circuit formation layer 12 to the circuit formation layer 32.

The chips 10, 20, and 30 each has a semiconductor substrate such as a silicon substrate, for example, and multilayer wiring. Active elements, such as transistors formed in active areas of silicon substrates, and multilayer wiring form the circuit formation layers 12, 22 and 32. Connection electrodes 14 and the connection electrodes 24 and 34 may be metal bumps such as CU bumps or solder bumps, for example. For example, the electrodes formed on the surfaces of the circuit formation layers 12 and 22 may be directly connected to each other without bumps. Hereinafter, connections between electrodes may be referred to as connection electrodes instead of being referred to as bumps, intending to include direct connections. Through electrodes 16 and the through electrodes 36 may be a metal layer such as a Cu layer. The substrate 40 may be a wiring substrate made of, for example, a glass epoxy substrate or the like. The wiring 48 is a metal layer such as a Cu layer or the like, for example. The connection electrodes 44 may be metal bumps such as solder balls. The circuit formation layer 12 includes a logic circuit 50, the circuit formation layer 22 includes a memory circuit 52, and the circuit formation layer 32 includes an interface circuit 54. Power may be supplied to the chip 20 via the through electrodes of the chip 10 and/or the chip 30, or alternatively through electrodes may further be provided in the chip 20 and power may be supplied from the opposite surface from the circuit surface of the chip 20. Since other structures are substantially the same as or similar to those illustrated in FIG. 2, descriptions therefor may be omitted.

In FIG. 6, the logic circuit 50 is connected to the memory circuit 52 via the connection electrodes 24. For this reason, signal lines 60 are densely wired as in FIG. 2. As a result, the communication band between the logic circuit 50 and the memory circuit 52 may be improved. Since the signal lines 60 do not pass via the through electrodes 16, the energy consumption during communication between the logic circuit 50 and the memory circuit 52 may be reduced. The logic circuit 50 is connected to the interface circuit 54 via the connection electrodes 24, the wiring 28, the connection electrodes 24, and the through electrodes 36. Since the number of signal lines 62 between the logic circuit 50 and the interface circuit 54 is smaller than that of the signal lines 60, the logic circuit 50 and the interface circuit 54 may be connected via the through electrodes 36, the density of which is low. For example, since the signal transmitted through the signal lines 62 is slower than the signal transmitted through signal lines 64, it may not be affected by the band limitation due to the parasitic capacitance of the through electrodes 36. The interface circuit 54 is coupled to the substrate 40 not via the through electrodes 16. For this reason, a high-speed signal is transmitted through the signal lines 64 because the parasitic capacitance of the through electrodes 16 is not added to the lines and the signal is not subjected to the band limitation. For example, because the chips 10 and 30 are mounted on the same plane, the number of stacked chips may be reduced. A semiconductor, the thickness of the stack chip of which may be reduced and which has excellent heat dissipation characteristics and power supply characteristics may be provided.

In FIG. 6, the chip 10, for example, as a first chip, is mounted on the substrate 40 with the circuit surface facing up and includes the logic circuit 50. The chip 20, for example, as a second chip, is mounted on the chip 10 with the circuit surface facing down and includes the memory circuit 52. The logic circuit 50 is electrically coupled to the memory circuit 52 via the connection electrodes 24, for example, first connection electrodes. The chip 30, for example, as a third chip is mounted on the substrate 40 and between the substrate 40 and the chip 20 alongside the chip 10, with the circuit face facing down, and includes the interface circuit 54. The interface circuit 54 converts a signal 63 input to or output from the logic circuit 50 or the memory circuit 52, for example, as a first signal to a signal 65 input to or output from the outside, for example, as a second signal. The transmission rate of the signal 65 is higher than that of the signal 63. The chip 30 includes the through electrodes 36, through which the signal 63 is transmitted, for example, as first through electrodes.

The logic circuit 50 is electrically coupled to the memory circuit 52 via the connection electrodes 24 not via through electrodes. For this reason, the number of the signal lines 60 may be increased and the communication band may be improved. In addition, the energy consumption during communication may be reduced. Since the high-speed signal 65 does not pass through the through electrodes 36, the influence of the band limitation on the signal 65 due to the parasitic capacitance of the through electrodes 36 may be reduced. As described above, each chip may be stacked appropriately.

The interface circuit 54 may be a circuit that converts the low-speed signal 63 into the high-speed signal 65. The signal 63 may be a parallel signal, the signal 65 may be a serial signal, and the interface circuit 54 may converts between the parallel signal and the serial signal. The transmission rate of the serial signal is higher than that of the parallel signal. For this reason, the influence of the band limitation to the serial signal due to parasitic capacitance of the through electrodes 36 may be reduced. For example, the interface circuit 54 may be a serial-signal speed-conversion circuit that converts between the serial signal 63 having a signal speed which the logic circuit 50 is able to process at and the serial signal 65 faster than the serial signal 63.

In addition, the chip 10 includes the through electrodes 16, for example, as second through electrodes. The number of the connection electrodes 24 is larger than that of the through electrodes 16. A large number of the connection electrodes 24 may improve the communication band between the logic circuit 50 and the memory circuit 52.

Since the number of the signal lines 62 is small and the transmission rate of the signal 63 is not high, the influence on the signal 63 may be small even though the signal 63 is transmitted between the logic circuit 50 and the interface circuit 54 via the chip 20. For example, the logic circuit 50 is electrically coupled to the interface circuit 54 via the chip 20.

The circuit formation layer 22 of the chip 20 may have an inverter or a buffer that amplifies a signal passing through the wiring 28. By doing so, attenuation of the signal due to the resistance and capacitance of the wiring 28 and attenuation of the signal due to the through electrodes 36 may be compensated for.

A control circuit may be mounted on the semiconductor device, the control circuit performing communication control between the chip 20 and the chip 30 in accordance with commands from the chip 10. With it, communication may be performed from the chip 20 through the chip 30 to the outside. For example, communication between the chip 10 and the outside may be performed via the memory circuit 52 of the chip 20 not via the wiring 28. In this case, the wiring 28 may be excluded. This semiconductor device does not have to include the substrate 40, and the same applies to other semiconductor devices.

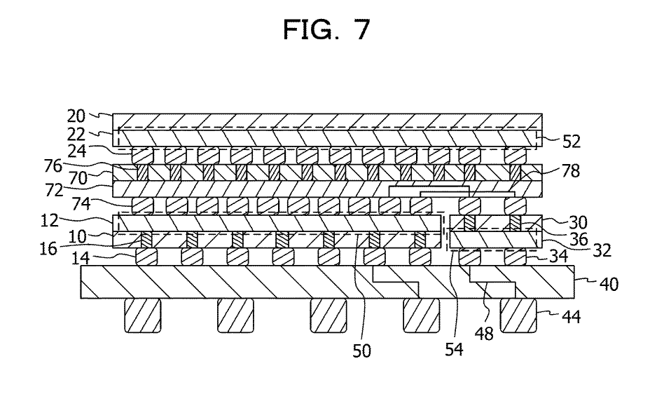

FIG. 7 illustrates an example of a cross-sectional view of a semiconductor device. As illustrated in FIG. 7, an interposer 70 is provided between a chip 10 and a chip 20 and between a chip 30 and the chip 20. Connection electrodes 74 are provided under the interposer 70. Through electrodes 76 connecting connection electrodes 24 and a circuit formation layer 72 are formed in the interposer 70. Wiring 78 electrically coupling the chips 10 and 30 to each other is provided in the circuit formation layer 72. The interposer 70 may be, for example, a silicon interposer using a silicon substrate having a high resistivity, a glass interposer using a glass substrate, or the like. A signal 61 is transmitted through the connection electrodes 74, the circuit formation layer 72, the through electrodes 76, and the connection electrodes 24. A signal 63 is transmitted through the connection electrodes 74, the wiring 78, the connection electrodes 74, and through electrodes 36. Since other structures are substantially the same as or similar to those illustrated in FIG. 6, descriptions therefor may be omitted.

As illustrated in FIG. 7, the signal 63 may be transmitted between a logic circuit 50 and an interface circuit 54 via the interposer 70 not via the chip 20. For example, the logic circuit 50 may be electrically coupled to the interface circuit 54 via the interposer 70 not via the chip 20. In FIG. 7, the signal 61 passes through the through electrodes 76. For example, in the interposer 70, mainly wiring is formed and no or a few active elements such as transistors are formed. For this reason, the density of the through electrodes 76 may be increased to about the same level of the connection electrodes 24. As a result, the number of signal lines 60 is increased, and the communication band may be improved. Since the interposer 70 includes a semiconductor substrate with a high resistivity or an insulating substrate, the parasitic capacitance of the through electrodes 76 may be reduced. Consequently, the energy consumption during communication may be reduced.

The circuit formation layer 72 may have an inverter or a buffer that amplifies a signal passing through the wiring 78. By doing so, attenuation of the signal due to the resistance and capacitance of the wiring 78 and attenuation of the signal due to the through electrodes 36 may be compensated for.

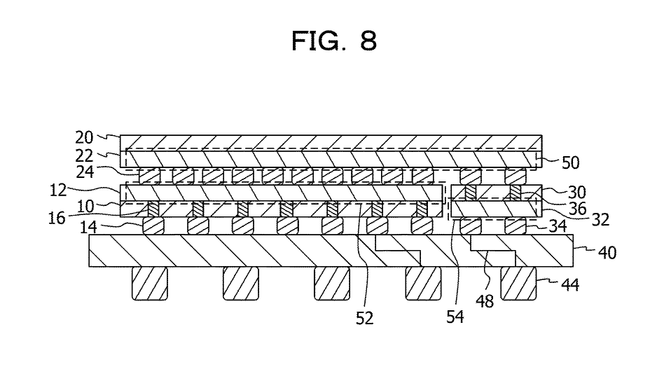

FIG. 8 illustrates an example of a cross-sectional view of a semiconductor device. As illustrated in FIG. 8, a circuit formation layer 12 includes a memory circuit 52 and a circuit formation layer 22 includes a logic circuit 50. A signal 63 is transmitted through connection electrodes 24 and through electrodes 36. Since other structures are substantially the same as or similar to those illustrated in FIG. 6, descriptions therefor may be omitted.

In FIG. 8, the signal 63 is able to be transmitted between the logic circuit 50 and an interface circuit 54 not via a chip 10. For example, the logic circuit 50 is electrically coupled to the interface circuit 54 not via the chip 10. For this reason, the wiring 28 illustrated in FIG. 6 may become unnecessary, and signal lines 62 may be shortened.

A first chip or a second chip may be a stacked body formed by stacking multiple chips. The first chip including a memory circuit as a main circuit element may be a stacked body.

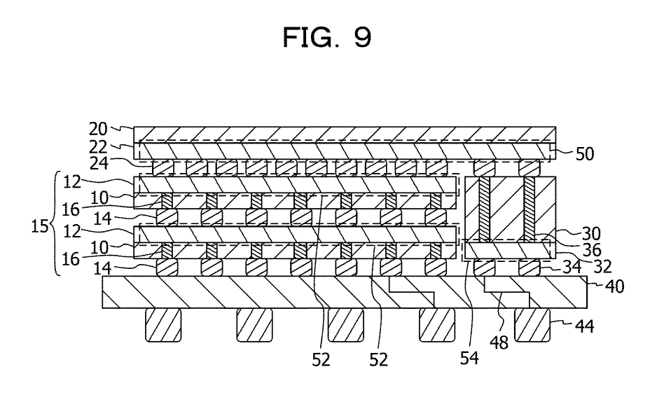

FIG. 9 illustrates an example of a cross-sectional view of a semiconductor device. As illustrated in FIG. 9, a stacked body 15 has multiple stacked chips 10. A circuit formation layer 12 of each chip 10 has a memory circuit 52. A chip 30 is not a stacked chip, and the thickness of the chip 30 corresponds to the total thickness of the stacked chips 10. Since other structures are substantially the same as or similar to those illustrated in FIG. 8, descriptions therefor may be omitted.

In FIG. 9, the area of the memory circuit 52 is smaller than that in FIG. 6. For this reason, the capacity of the memory circuit 52 is not increased. In FIG. 9, multiple chips 10 are stacked. For this reason, the capacity of the memory circuit 52 may be increased. A chip including a memory control circuit such as a memory interface circuit and a memory controller circuit may be provided on the side of a stacked body 15 facing a chip 20. With the memory control circuit, the stacked body 15 is used as a single high-speed large-capacity memory, even if a memory, operation of a basic element of which is slow, such as DRAM, is used. Through electrodes 36 are long, which increases capacitive load component. The speed of a signal 63 is low and may not be affected by the band limitation. Since lateral wiring is not provided in FIG. 9, signal lines 62 may be shortened compared to FIGS. 6 and 7.

As described above, a first chip including a memory circuit as a main circuit element may be a stacked body. As another example, a first chip may include a logic circuit as a main element and a stacked body in which a second chip includes a memory circuit as a main circuit element may be provided. In this case, the wiring 28 in FIG. 6 may be provided in the lowermost layer of the second stacked body. A chip including a memory control circuit may be provided on the side of the stacked body 15 facing the chip 10. A first chip or a second chip, which includes a logic circuit as a main element, may be a stacked body. Both the first chip and the second chip may be stacked bodies.

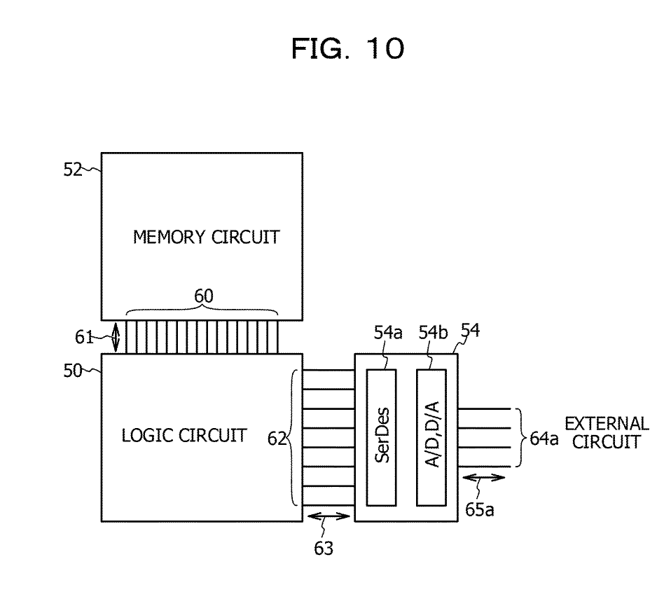

FIG. 10 is a block diagram of a semiconductor device. As illustrated in FIG. 10, an interface circuit 54 includes a SerDes circuit 54a and an A/D, D/A circuit 54b. The SerDes circuit 54a converts between a signal 63, which is a parallel signal, and a serial digital signal. The A/D, D/A circuit 54b converts the serial digital signal output by the SerDes circuit 54a into an analog signal 65a, and outputs the analog signal 65a to analog signal lines 64a. The A/D, D/A circuit 54b converts the analog signal 65a input from the analog signal lines 64a into a serial digital signal and outputs the serial digital signal to the SerDes circuit 54a. Other structures may be substantially the same as or similar to those illustrated in FIG. 8, and descriptions therefor may be omitted.

In FIG. 10, the interface circuit 54 includes the SerDes circuit 54a, for example, as a first conversion circuit, and the A/D, D/A circuit 54b, for example, as a second conversion circuit. The SerDes circuit 54a converts between the signal 63, which is a parallel signal, and a serial signal. The A/D, D/A circuit 54b converts between the serial signal and the analog signal 65a. Since the analog signal 65a is not transmitted via through electrodes 36, the analog signal 65a may be unlikely to be affected by signal deterioration and/or band limitation due to the capacitive load component. The interface circuits 54 illustrated in FIGS. 6 to 9 may include an A/D, D/A circuit 54b as in FIG. 10.

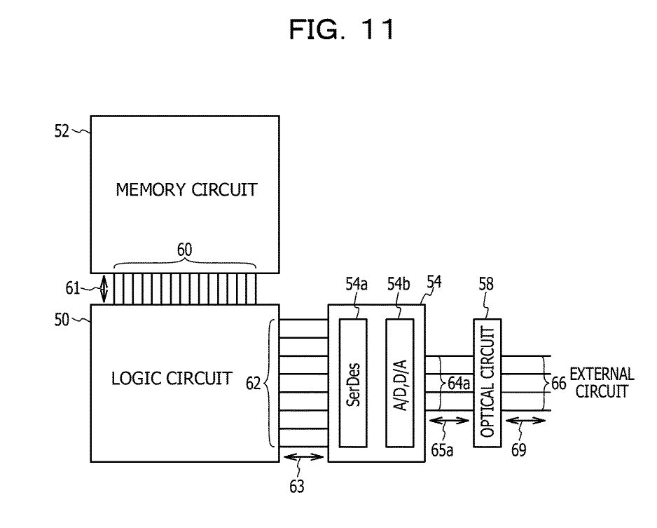

FIG. 11 illustrates an example of a block diagram of a semiconductor device. As illustrated in FIG. 11, an optical circuit 58 is provided which converts between an analog signal 65a and an optical signal 69. The optical signal 69 is transmitted through optical waveguides 66.

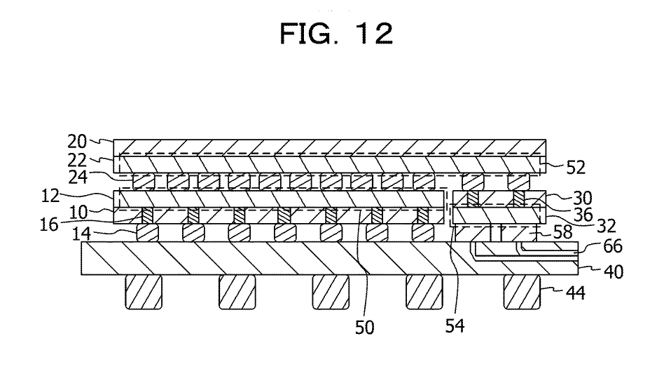

FIG. 12 illustrates an example of a cross-sectional view of a semiconductor device. As illustrated in FIG. 12, an optical circuit 58 is provided between a substrate 40 and a chip 30. The optical waveguides 66 is provided in the substrate 40.

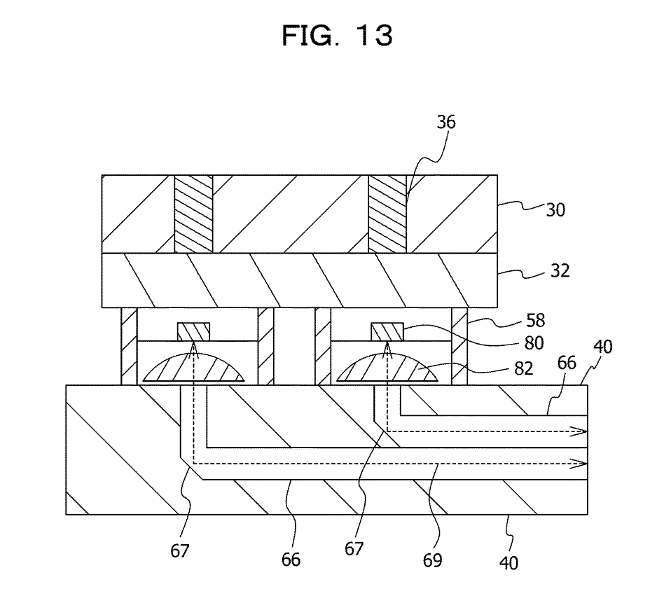

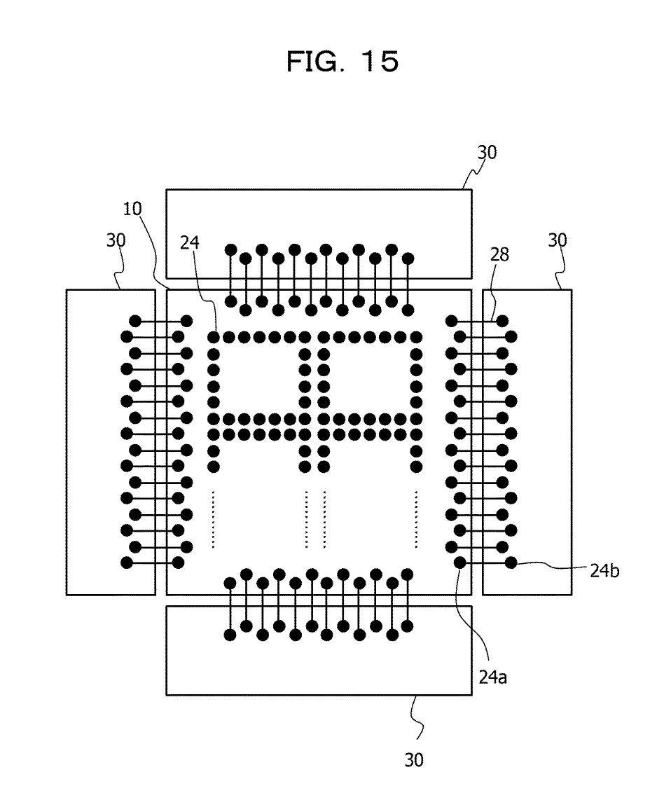

FIG. 13 illustrates an example of an enlarged view around an optical circuit. The optical circuit illustrated in FIG. 13 may be the optical circuit illustrated in FIG. 12. As illustrated in FIG. 13, an optical circuit 58 includes light source and light reception elements 80 and lenses 82. The light source and light reception element 80 converts an analog signal 65a output by an interface circuit 54 into an optical signal 69, and outputs the optical signal 69 to an optical waveguide 66. The light source and light reception element 80 converts the optical signal 69 propagating through the optical waveguide 66 into an analog signal, and outputs the analog signal to the interface circuit 54. The lens 82 optically couples the light source and light reception element 80 and the optical waveguide 66. A Mirror 67 reflects an optical signal 69. Other structures may be substantially the same as or similar to those illustrated in FIG. 15, and descriptions therefor may be omitted.

In FIG. 13, the optical circuit 58 that converts between the analog signal 65a and the optical signal 69 is provided, for example, as a third conversion circuit. Since through electrodes 36 are not provided between a substrate 40 and the interface circuit 54, the distance between the interface circuit 54 and the optical circuit 58 may be reduced. The optical circuit 58 is provided between a chip 30 and the substrate 40. For this reason, the transmission distance of the lossy analog signal may be shortened.

The signal obtained by mixing the optical signal 69 and an electrical signal may be used for the signal between the interface circuit 54 and an external circuit. The optical waveguides 66 may be provided on a surface of the substrate 40, for example, on the upper surface or the lower surface. The optical waveguides 66 may be provided both in the inside and a surface of the substrate 40. The substrate 40 may not have the optical waveguides 66 and may have openings that the optical signals 69 pass through, and the optical circuit 58 may be directly coupled to optical waveguides of a substrate under the substrate 40. The semiconductor devices illustrated in FIGS. 6 to 9 may have an optical circuit 58.

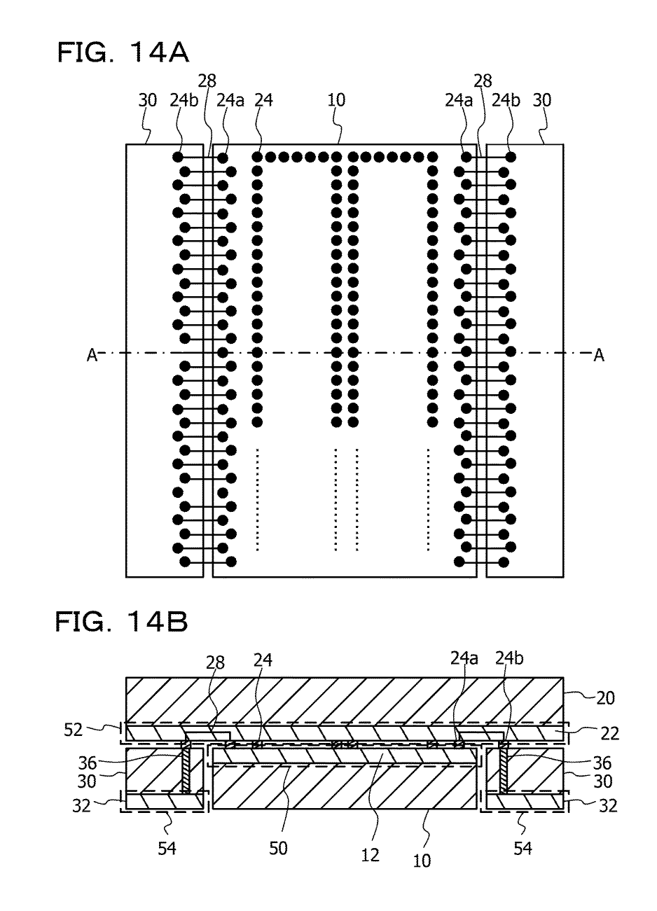

FIG. 14A illustrates an example of a plan view of a semiconductor device. FIG. 14B illustrates an example of a cross-sectional view taken along line A-A in the semiconductor device. FIG. 14A illustrates upper surfaces of chips 10 and 30 and wiring 28. As illustrated in FIGS. 14A and 14B, the chips 30 are provided on both sides of the chip 10. A circuit formation layer 12 of the chip 10 includes a logic circuit 50, a circuit formation layer 22 of a chip 20 includes a memory circuit 52, and a circuit formation layer 32 of each chip 30 includes an interface circuit 54. Connection electrodes 24 for coupling the logic circuit 50 and the memory circuit 52 are provided in the form of a grid array on the upper surface of the chip 10. Connection electrodes 24a are provided for coupling the logic circuit 50 to the wiring 28 on the chip 30 side of the upper surface of the chip 10. On the upper surface of the chip 30, connection electrodes 24b are provided for connecting the interface circuit 54 to the wiring 28. Other structures may be substantially the same as or similar to those illustrated in FIG. 6, and descriptions therefor may be omitted.

FIG. 15 illustrates an example of a plan view of a semiconductor device. As illustrated in FIG. 15, chips 30 are provided on the four sides of a chip 10. Other structures may be substantially the same as or similar to those illustrated in FIGS. 14A and 14B, and descriptions therefor may be omitted.

In FIGS. 14A, 14B, and 15, the multiple chips 30 are provided around the chip 10. For this reason, since the connection electrodes 24a is able to be arranged along the multiple side of the chip 10, the number of signal lines 62 may be increased. The multiple chips 30 may be chips each including an interface circuit 54 of the same type, or chips each including an interface circuit 54 of a different type. Chips each including an interface circuit 54 of the same time may be chips having the same shape.

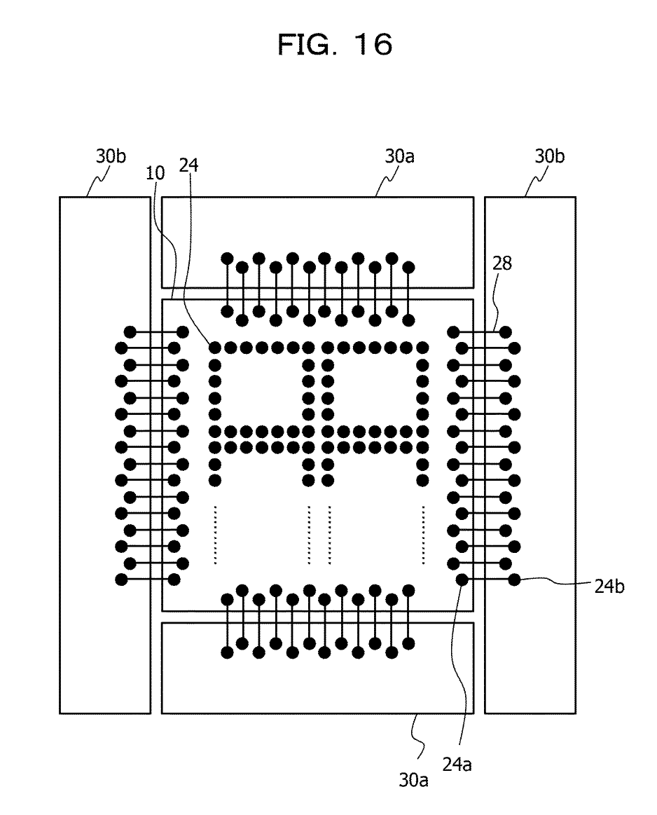

FIG. 16 illustrates an example of a plan view of a semiconductor device. As illustrated in FIG. 16, chips 30a are provided on respective two sides facing each other of a chip 10, and chips 30b are provided on respective another two sides facing each other of the chip 10. The chips 30a and the chips 30b may be chips including interface circuits 54 of different types. Other structures may be substantially the same as or similar to those illustrated in FIG. 15, and descriptions therefor may be omitted.

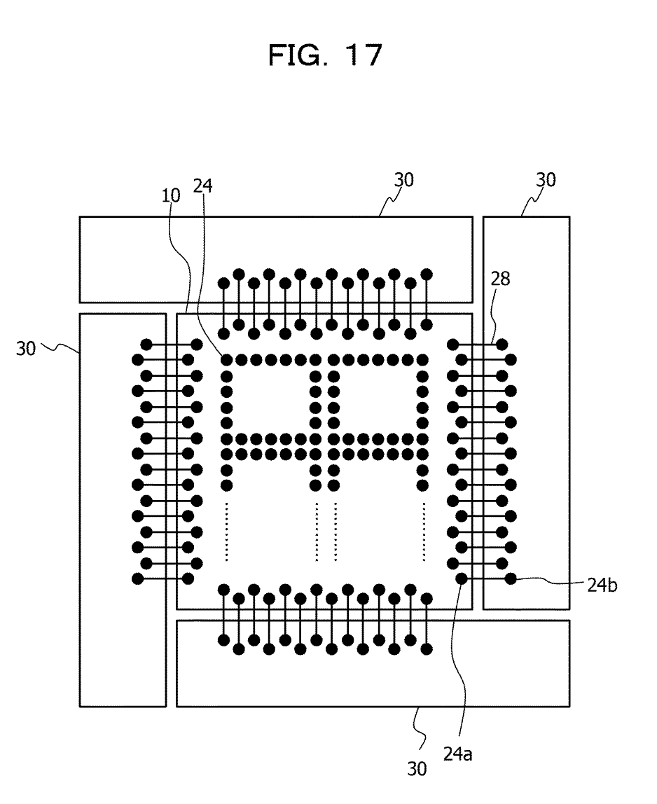

FIG. 17 illustrates an example of a plan view of a semiconductor device. As illustrated in FIG. 17, a chip 10 has a square shape and the planar shapes of four chips 30 are congruous. For this reason, the four chips 30 may be chips each including an interface circuit 54 of the same type. The chip 10 may have a rectangular shape, and the planar shapes of the four chips 30 may be different. Other structures may be substantially the same as or similar to those illustrated in FIG. 16, and descriptions therefor may be omitted.

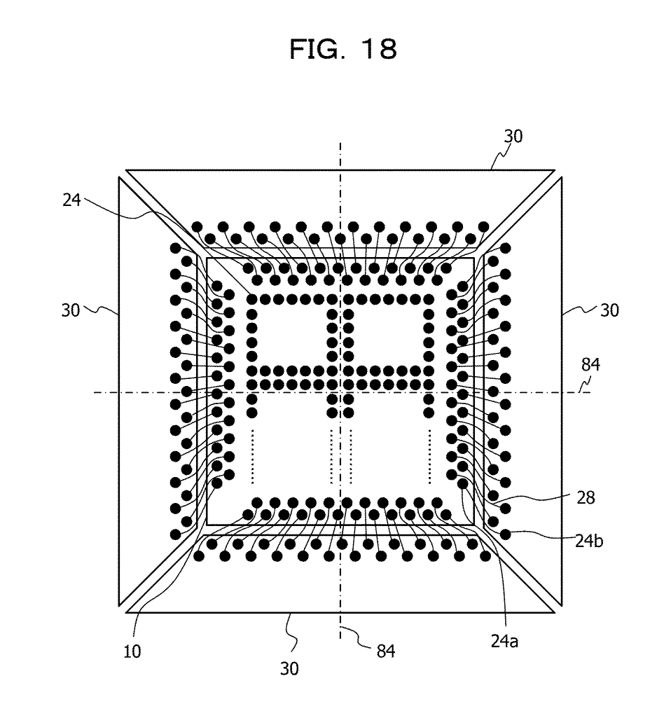

FIG. 18 illustrates an example of a plan view of a semiconductor device. As illustrated in FIG. 18, four chips 30 each have a trapezoidal shape. The short side of the parallel sides of the trapezoid of the chip 30 is formed along a side of a chip 10. The oblique sides of the trapezoid of the chip 30 are each formed along an oblique side of another chip 30. Wiring 28 is provided such that the wiring intervals are wider toward the outer side. Although the chip 10 may have a rectangular shape, making the chip 10 a square shape may make the planar shapes of the chips 30 congruous. Other structures may be substantially the same as or similar to those illustrated in FIG. 17, and descriptions therefor may be omitted.

As in FIGS. 16 to 18, by designing the outer perimeters of the chips 30a and chips 30b or the outer perimeter of the area of the combined four chips 30 to be rectangular, the mounting area may be used efficiently.

As in FIG. 18, when chips 30 are designed to be trapezoidal, the intervals between connection electrodes 24b are larger than those of connection electrodes 24a. The planar shapes are symmetrical with respect to the two lines 84 passing through the center of the chip 10 and parallel to the sides of the chip 10. For this reason, the influence of thermal expansion distortion may be reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
a first chip including one of a logic circuit and a memory circuit and mounted over a substrate with a circuit surface of the first chip facing up;
a second chip including the other of the logic circuit and the memory circuit and mounted over the first chip with a circuit surface of the second chip facing down such that the logic circuit and the memory circuit are electrically coupled to each other via a first connection electrode; and
a third chip mounted between the substrate and the second chip with a circuit surface of the third chip facing down and alongside the first chip, the third chip including:
an interface circuit that converts between a first signal which is input to and output from the logic circuit or memory circuit and a second signal which has a signal speed higher than the first signal and is input to and output from an outside; and
a first through electrode electrically coupling the logic circuit or memory circuit and the interface circuit.

2. The semiconductor device according to claim 1, wherein
the interface circuit converts between the first signal which is a parallel signal and the second signal which is a serial signal.

3. The semiconductor device according to claim 1, wherein
the interface circuit includes a circuit that converts between the first signal which is a serial signal and the second signal which is a serial signal faster than the first signal.

4. The semiconductor device according to claim 1, wherein
the first chip includes a second through electrode, and
a number of the first connection electrodes is larger than a number of the second through electrodes.

5. The semiconductor device according to claim 1, wherein
the first chip includes the logic circuit,
the second chip includes the memory circuit, and
the logic circuit and the interface circuit are electrically coupled to each other via the second chip.

6. The semiconductor device according to claim 1, wherein
the first chip includes the logic circuit,
the second chip includes the memory circuit,
an interposer is provided between the second chip and the first chip and between the second chip and the third chip, and
the logic circuit and the interface circuit are electrically coupled to each other via the interposer and not via the second chip.

7. The semiconductor device according to claim 1, wherein
the first chip includes the memory circuit,
the second chip includes the logic circuit, and
the logic circuit and the interface circuit are electrically coupled to each other not via the first chip.

8. The semiconductor device according to claim 1, wherein
the first chip or the second chip includes a stacked body formed by stacking a plurality of chips.

9. The semiconductor device according to claim 8, wherein
the first chip is the stacked body formed by stacking the plurality of chips, and
a thickness of the third chip corresponds to a total thickness of the stacked body.

10. The semiconductor device according to claim 8, wherein
the chips each including a memory circuit are stacked in the stacked body, and one of the chips on a side facing the second chip including the logic circuit of the stacked body includes a memory control circuit.

11. The semiconductor device according to claim 1,
the interface circuit includes a first conversion circuit that converts between the first signal, which is a parallel signal, and a serial signal, and a second conversion circuit that converts between the serial signal and an analog signal.

12. The semiconductor device according to claim 11, further comprising a third conversion circuit that converts between the analog signal and an optical signal.

13. The semiconductor device according to claim 12, wherein
the third conversion circuit is provided between the third chip and the substrate.

14. The semiconductor device according to claim 1, wherein
the third chip and another third chip are provided around the first chip.

15. The semiconductor device according to claim 1, wherein
the first chip and the third chip are mounted over the substrate using a second connection electrode.
